(19) United States
(12) Patent Application Publication
(10) Pub. No.: US 2020/0052141 A1
(43) Pub. Date: Feb. 13, 2020

(54) METHOD AND DEVICE FOR LOW COST, HIGH EFFICIENCY STEP PHOTOVOLTAIC CELLS

(71) Applicants: Khalifa University of Science and Technology, Abu Dhabi (AE); Massachusetts Institute of Technology, Cambridge, MA (US)

(72) Inventors: Sabina ABDUL HADI, Abu Dhabi (AE); Ammar Munir NAYFEH, Dubai (AE); Eugene A. FITZGERALD, Cambridge, MA (US)

(21) Appl. No.: 16/343,075

(22) PCT Filed: Oct. 12, 2017
(86) PCT No.: PCT/US2017/056335

§ 371 Date: Apr. 18, 2019

Related U.S. Application Data
(60) Provisional application No. 62/409,891, filed on Oct. 19, 2016.

(51) Int. Cl. H01L 31/0725; H01L 31/074; H01L 31/043

(52) U.S. Cl. CPC H01L 31/0725; H01L 31/043; H01L 31/074

(57) ABSTRACT

A multi-junction solar cell includes a plurality of photovoltaic cell layers that are electrically connected and stacked to define upper and lower subcells having at least one step difference therebetween that exposes portions of the lower subcell such that, responsive to incident illumination, a current density of the exposed portions of the lower subcell is greater than that of portions thereof having the upper subcell thereon. Related devices and fabrication methods are also discussed.

### CLAIM OF PRIORITY

This application claims the benefit of and priority under 35 U.S.C. § 119(e) from U.S. Provisional Patent Application No. 62/409,891, entitled “METHOD AND DEVICE FOR LOW COST, HIGH EFFICIENT STEP PHOTOVOLTAIC CELLS” and filed Oct. 19, 2016, in the United States Patent and Trademark Office, the disclosure of which is incorporated by reference herein in its entirety.

### FIELD

This disclosure relates to the fabrication and the use of photovoltaic cells, and more particularly, photovoltaic step cells with improved efficiencies and reduced cost of production.

### BACKGROUND

The “background” description provided herein is for the purpose of generally presenting the context of the disclosure. Work described in this background section, as well as aspects of the description which may not otherwise qualify as prior art at the time of filing, are neither expressly nor impliedly admitted as prior art against the present disclosure.

A goal in the solar industry is achieving high solar conversion efficiency at a low cost. Although silicon solar cells may be abundant and inexpensive, as single junction cells they may have conversion efficiency of up to about 26%. Adding an additional higher bandgap based solar cell above the silicon cell, thereby forming a multi-junction (MJ) cell, can increase conversion efficiency of solar cell. Multi-junction solar cells may be formed as a stack of two or more subcells that are electrically connected either in series or parallel setup. A benefit of MJ cells is that the lattice thermalization losses in each subcell material are reduced due to tuning of the subcells bandgaps (E_{g}) to the energy of incident photons (E). In multi-junction solar cells connected in series, the material with higher bandgap (E_{gT}) is typically placed on top to absorb larger energy photons, while material with smaller bandgap (E_{gB}<E_{gT}) is placed underneath and absorbs the remaining filtered light with lower energy photons. This way, photon energy capture may be maximized and used more efficiently and less energy may be wasted through lattice thermalization.

In one example, an efficiency (˜38%) of a two junction (2J) solar cell connected in series may be achieved if the bottom cell bandgap, E_{gB}, is ˜0.9-1.1 eV, while E_{gT} of top cell is ˜1.7 eV. Si (E_{g}=1.12 eV) based tandem cells with a top GaAsₓP₁₋ₓ cell (E_{g}=2.22-1.42 eV for x=0-1) may be attractive to create low cost, Si based dual junction solar cells. The performance of MJ cells connected in series may be determined by the smallest individual current generated in each subcell, which may be referred to as the limiting current. The subcell with the lowest optically generated current limits current flow in tandem cell, decreasing its overall efficiency. For improved or optimum MJ solar cell performance, current generated in all subcells should match. In some traditional MJ solar cells, the improvement or optimization of tandem cell performance may be focused on achieving the highest possible limiting current holding all cell areas constant, where the current density is matched across the cells by changing the subcell thickness.

The top cell may be deposited (“grown”) on top of the bottom cell, which may be referred to as a monolithic approach, or the two subcells may be individually fabricated and later mechanically bonded. In a monolithic approach, top cell material may be lattice matched to the crystal lattice of the bottom cell in order to achieve high quality devices. This may require growth of buffer layers prior to top cell formation, which may often lead to optical loss in the buffer layers, decreasing bottom cell current and inhibiting performance of the tandem cell. Mechanical bonding may not have such material quality constraints but may involve challenges in separation of cell layers from the carriers, or lift-off, and further transfer to another cell/carrier, via bonding process, while maintaining high quality interface. Presently industry available lift-off processes may be relatively slow and thus may require processing of small pieces. Such constraints may limit scalability of MJ solar cell manufacturing and prevent cost scaling, resulting in higher prices of MJ solar cells.

### SUMMARY

According to some embodiments, a multi-junction solar cell includes a plurality of photovoltaic cell layers that are electrically connected and stacked to define upper and lower subcells having at least one step difference therebetween that exposes portions of the lower subcell such that, responsive to incident illumination, a current density in or of the exposed portions of the lower subcell is greater than that of portions thereof having the upper subcell thereon. The photovoltaic cell layers may include respective p-n junctions, and may be electrically connected in series in some embodiments.

According to further embodiments, a method of fabricating a multi-junction solar cell includes providing a plurality of photovoltaic cell layers that are electrically connected and stacked to define upper and lower subcells having at least one step difference therebetween that exposes portions of the lower subcell such that, responsive to incident illumination, a current density in or of the exposed portions of the lower subcell is greater than that of portions thereof having the upper subcell thereon.

In some embodiments, responsive to the incident illumination, the exposed portions of the lower subcell may be configured to generate a greater portion of a respective output current thereof than portions thereof having the upper subcell thereon.

In some embodiments, the exposed portions of the lower subcell may be free of conductive contact layers thereon.

In some embodiments, the photovoltaic cell layers may be configured such that, responsive to the incident illumination, respective current densities of the upper and lower subcells are different. For example, the photovoltaic cell layers may have different thicknesses and/or may be formed of materials having different bandgaps such that the respective current densities of the upper and lower subcells are different.

In some embodiments, responsive to the incident illumination, the photovoltaic cell layers may be configured to generate respective output currents that are substantially equal. For example, a surface area of the exposed portions of the lower subcell relative to a surface area of the upper subcell may be configured such that the respective output currents thereof are substantially equal responsive to the incident illumination.

In some embodiments, the upper subcell may be a patterned epitaxial photovoltaic cell layer that defines the at least one step difference. For example, a photovoltaic cell layer may be formed using an epitaxy process and patterned to define the upper subcell and the at least one step difference.

In some embodiments, the upper subcell may be mechanically bonded to the lower subcell. For example, a photovoltaic cell layer may be formed on a carrier substrate (such as a lattice-matched substrate) using the epitaxy process prior to the patterning, the upper subcell may be mechanically bonded to the lower subcell responsive to the patterning, and the upper subcell may be separated from the carrier substrate.

In some embodiments, the carrier substrate may be a first monocrystalline substrate, and a second photovoltaic cell layer may be formed on a second monocrystalline substrate to define the lower subcell (for example, using an epitaxy process) prior to the mechanical bonding.

In some embodiments, the lower subcell may be silicon (Si), and the upper subcell may be gallium arsenide phosphide (GaAsP).

In some embodiments, at least one buffer layer may be formed on lower subcell, and the upper subcell may be formed on the at least one buffer layer opposite the lower subcell using the epitaxy process such that the photovoltaic cell layers define a monolithic structure.

In some embodiments, the at least one buffer layer may be patterned or may include a patterned layer that defines a portion of the at least one step difference and exposes the portions of the lower subcell.

In some embodiments, the lower subcell may be a monocrystalline layer.

In some embodiments, the lower subcell may be silicon (Si), the upper subcell may be gallium arsenide phosphide (GaAsP), and the at least one buffer layer may be graded silicon germanium (SiGe) or graded GaAsP graded for lattice matching.

In some embodiments, the upper subcell may include pyramid structures, cones, nano-rods, and/or nano-wires that define the at least one step difference.

In some embodiments, the upper subcell and the lower subcell may be formed of respective materials that are configured to generate different output currents responsive to the incident illumination at a beginning-of-life based on degradation of the respective materials, and to subsequently generate substantially equal output currents responsive to the incident illumination.

Other devices and methods according to embodiments described herein will be or become apparent to one with skill in the art upon review of the following drawings and detailed description. It is intended that all such additional devices and methods be included within this description, be within the scope of the present inventive subject matter, and be protected by the accompanying claims. Moreover, it is intended that features disclosed herein can be implemented separately or combined in any way and/or combination.

### BRIEF DESCRIPTION OF THE DRAWINGS

A more complete appreciation of the disclosure and many of advantages thereof will be understood by reference to the following detailed description when considered in connection with the accompanying drawings, wherein:

FIGS. 1A-1E illustrate a cross-section example of a step-cell fabrication process, involving layer transfer and bonded step-cell according to some embodiments of the present disclosure.

FIGS. 2A-2B illustrate another cross-section example of a step-cell fabrication process that can be used for improvement or optimization of monolithic tandem cells according to some embodiments of the present disclosure.

FIGS. 3A-3E show a top or plan view perspective of design variations of a step-cell according to some embodiments of the present disclosure. More particularly, FIGS. 3A-3B show designs that may be used in monolithic step-cells and FIGS. 3C-3E show designs that may be used for lift-off of bonded step-cells, according to some embodiments of the present disclosure.

FIG. 4A is a schematic representation of a dual junction step-cell design according to some embodiments of the present disclosure, which may be used for theoretical analysis.

FIGS. 4B and 4C are graphs showing effects of boosted photogeneration on subcell current and voltage, respectively, according to some embodiments of the present disclosure.

FIG. 5 is a graph showing theoretical efficiency of a step cell as a function of Aₜₒₜₐₗ/Aₜₒₚ ratio for improved or optimized bandgap combinations for each Aₜₒₜₐₗ/Aₜₒₚ ratio (from 1-2) according to some embodiments of the present disclosure.

FIG. 6 is a graph that plots an efficiency upper limit of a Si-based 2J step-cell versus top cell bandgap according to some embodiments of the present disclosure.

FIG. 7 is a graph showing the theoretical efficiency upper limit of Si-based step-cell with top bandgap E_{gT}=1.767 eV for varying quality of the bottom Si cell, expressed as quantum efficiency (QE=0.2-1), according to some embodiments of the present disclosure.

FIGS. 8A-8B show cross-sections of GaAs_{0.71}P_{0.29}/Si tandem step-cells with tunnel diode (TD) for variable Aₜₒₜₐₗ/Aₜₒₚ ratio with a SiGe graded buffer layer (FIG. 8A) and bonded cells (FIG. 8B), according to some embodiments of the present disclosure. Aₜₒₜₐₗ/Aₜₒₚ=1 may represent a conventional tandem cell.

FIG. 9 is a graph that depicts simulated cell efficiency as a function of top cell absorber layer thickness according to some embodiments of the present disclosure.

FIG. 10 illustrates bottom cell junction formation according to some embodiments of the present disclosure.

FIGS. 11A-11B are schematic diagrams of 2-terminal monolithic embodiments of the present disclosure showing an epitaxially grown stack (FIG. 11A) and a final step cell (FIG. 11B).

FIG. 12 illustrates fabrication steps used for bonded GaAsP/Si step cell manufacturing according to some embodiments of the present disclosure.

### DETAILED DESCRIPTION OF EMBODIMENTS

In embodiments of the present disclosure, a low cost multi-junction solar cell (also referred to herein as a tandem cell) can be fabricated, in which photovoltaic cell layers comprising respective p-n junctions are stacked to define a step difference between upper or top cell(s) and bottom or lower cell(s) such that a fraction of the bottom or lower cell(s) is exposed to unfiltered incident light in a step-like manner, boosting performance of the bottom or lower cell(s). This structure is referred to herein as a step-cell, where the top or upper cell(s) and bottom or lower cell(s) define subcells of the structure. The step-cell features can facilitate cost effective manufacturing of bonded multi-junction solar cells that may require lift-off and layer transfer. Top or upper cell layers grown on a carrier substrate are patterned into step-cell features and are then bonded to a bottom or lower cell (for example, a silicon (Si) bottom cell), where a step-cell design can facilitate fast lift-off using conventional equipment, allowing re-use of carrier substrates. This method of fabricating the step-cell may be more economical to manufacture than traditional multi-junction solar cells.

In monolithic multi-junction solar cells, step-cell design can be used to mitigate parasitic optical losses in buffer layers. Analysis showed that step-cell design may relax bandgap requirements for efficient tandem cell. Theoretical analyses showed that a GaAs (1.41 eV) top or upper cell on silicon may have an upper efficiency limit of about 21% in a conventional tandem cell, but the efficiency can increase to about 38.7% or more for step-cell designs according to some embodiments of the present disclosure. As a result, step-cell designs according to some embodiments of the present disclosure can provide added design optimization parameters and an opportunity for wider selection of materials used in tandem solar cell applications.

In a step-cell design and process according to some embodiments of the present disclosure, parts or portions of the top or upper cell material are removed, defining a step difference that exposes the underlying substrate (or cell layer). In the step-cell, current is matched between the subcells, but the current density in each subcell can be different. Thus, the step-cell creates additional design freedom not available in the traditional MJ cell. In monolithic tandem cells, step-cell designs according to some embodiments of the present disclosure can help mitigate some optical losses incurred in buffer layer. For mechanically bonded tandem cells, the removal of regions of the top or upper cell area allows for fast and cost-effective layer transfer of top or upper cell material and its subsequent bonding to the bottom or lower cell. This approach may not require any special equipment and may allow for recycling of the substrate with a buffer that may be used to create an improved or optimal top-band-gap subcell, which may drastically lower the production cost of such tandem step cells.

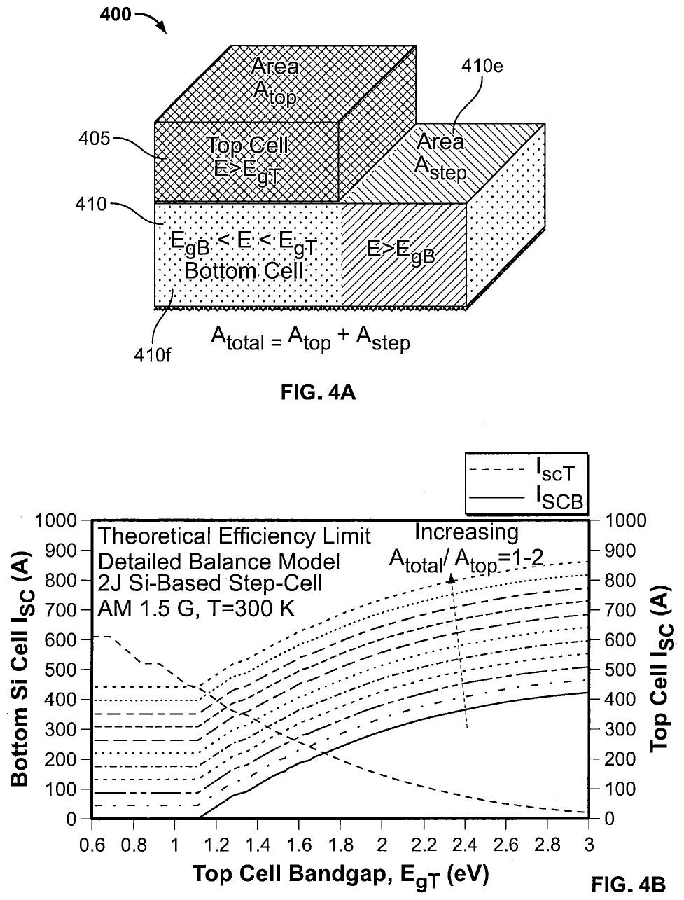

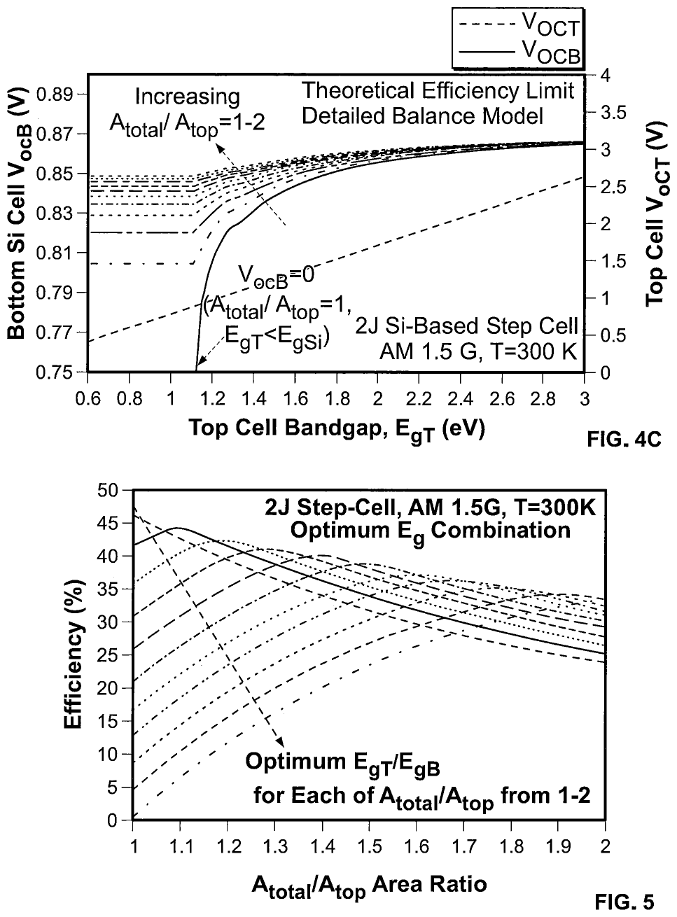

Exposing parts of the bottom cell or lower cells directly to the incident sunlight boosts photogenerated current in the bottom or lower cell(s). For example, FIGS. 4B and 4C illustrate effects of boosted photogeneration on a bottom cell short circuit current (Isc) and open circuit voltage (Voc), as described in greater detail below. The exposed area of the bottom or lower cell can be varied to achieve matching electrical currents in the two (or more) subcells. Although the matching of currents is not essential in the step-cell design, it may reduce or minimize the total area to achieve the power output, thus reducing or minimizing cost. Also, matching current may ensure that neither of the cells acts as a load on the other cell, which may otherwise lead to thermal heating and reliability problems in the subcell generating lower current. It is noted that embodiments described herein are not limited to photovoltaic cell stack structures having two junctions, but may include stacks of photovoltaic cell layers with three or more junctions, with each layer defining a step difference relative to the layer on which it is stacked.

In a first embodiment, a low cost fabrication method is provided for a dual-junction step-cell where the top layer is patterned for enhanced dual-junction performance. In particular, the top or upper cell layer is grown on lattice matched crystalline substrate that contains an upper sacrificial etch-release layer. The substrate is made from a single crystalline wafer or a carrier with latticed matched graded buffer. The top or upper cell is patterned into step-cell features for dual-junction performance, which exposes the underlying etch-release layer. The patterned structure is bonded to a bottom or lower cell layer, defining a step difference that exposes portions of the surface of the bottom or lower cell layer. The bottom layer can be Si or other suitable materials or composites. The etch-release layer is treated with lift-off chemicals removing the etch-release layer and releasing the crystalline carrier from the patterned top or upper cell bonded to the bottom or lower cell layer. The bonded dual junction step-cell is inverted for use in capturing solar energy.

In related embodiments, the patterning of the top or upper cells in step cell uses pyramid structures, or is replaced by cones, nano-rods or nano-wires for improving or maximizing optical absorption.

In other related embodiments, the lattice matched carrier wafer, with or without a metamorphic layer, is used for further growth of additional top-cell layers.

In still other embodiments, the patterned, bonded dual junction step-cell is subjected to further solar cell processing that includes a metallization step, an anti-reflective coating step, and/or other steps to enhance performance.

In a second embodiment, a monolithic dual junction solar cell connected in series is fabricated. In particular, a bottom cell (such as Si) is fabricated. Lattice matched buffer layers are grown in cases where they may be required. A conducting layer or layers (e.g., tunnel diode) is grown to provide electrical connection between the top and bottom cells. Top or upper cell layers are grown, which can include but are not limited to: back surface field, absorber layer, emitter layer, window layer, etc. The order of forming the buffer layers to conducting layers described herein can be interchanged, depending on the characteristics of conducting layer. Also, growth of the buffer layers can be completely avoided or omitted in case high quality of the top or upper cell material can be achieved without it. Next, all layers above the bottom or lower cell are patterned to define step differences in such way that they expose bottom or lower cell to unfiltered solar irradiation. Pattern design may be selected for improved or optimized dual junction step cell performance. In an alternative embodiment, patterning step(s) can be omitted in case that all layer(s) on the top of the bottom or lower cell are grown in the form of nano-rods, nano-cones or other pre-patterned features.

In related embodiments for monolithic dual junction step-cell, the bottom cell is Si, a buffer layer for lattice matching is graded SiGe or graded GaAsP, and the top cell is GaAsP.

In other embodiments for monolithic dual junction solar cells, the step-cell design is used to boost photogenerated current in the bottom or lower cell, which may be limited by the absorption in buffer layer.

In a third embodiment, the topography or patterning of the cell is varied (for either monolithic or bonded step-cells) to achieve design and processing improvement and/or optimization. In other embodiments, the bonded, lift-off step cells can be connected into large area solar devices by using metal interconnects. In yet other embodiments, top cell fabrication can use nano-cones or nano-wires.

In a fourth embodiment, the step-cell is designed for subcell performance variation during up to the entire life cycle of the tandem solar cell in the field. In this embodiment, the degradation of subcells for a given operating environment differs based on different materials selected for the sub cells.

Example: Fabrication of Low Cost Bonded Dual-Junction Step-Cell.

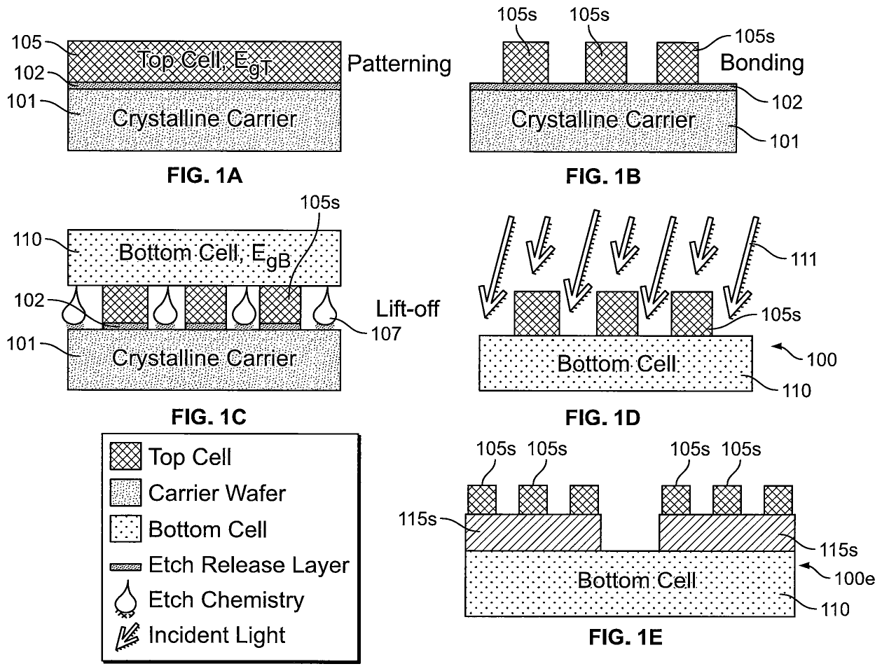

Referring now to the drawings, FIGS. 1A-1D are schematic cross-section illustrations of a method to produce a low cost bonded dual-junction step-cell 100 according to some embodiments of the present disclosure. The top or upper cell layers 105, along with sacrificial etch-release layer 102, are grown on lattice matched crystalline substrate 101 (FIG. 1A). The substrate 101 is made from a single crystalline wafer or a carrier with latticed matched graded buffer layer(s). In FIG. 1B, the top cell 105 is patterned into step-cell features 105s, which may have a pitch or separation distance between the step-cell features 105s that is selected to improve or optimize dual-junction performance. Although illustrated primarily herein as step-shaped structures, the patterning of top cell 105 can define step features 105s including pyramid structures, cones, nano-rods or nano-wires for increasing or maximizing optical absorption.

The patterning exposes the etch-release layer 102, as depicted in FIG. 1B. The patterned structure 105s is bonded to the bottom cell 110 (for example, a Si bottom cell 110), as shown in FIG. 1C. After bonding, the etch-release layer 102 is accessed and removed using lift-off chemicals 107 underneath the smaller-sized “pillars” 105s of the top cell 105.

In FIG. 1D, the final cross-section of an inverted bonded dual junction step-cell 100 is shown, where the patterned top cell 105s define step differences that expose portions of the bottom cell 110 to incident illumination 111. The inverted patterned and bonded dual junction step-cell 100 can be subjected to solar cell processing that includes a metallization step and anti-reflective coating steps that are selected and/or optimized for the step-cell design 105s. The lattice matched carrier wafer 101, with or without metamorphic layers, can be re-used for further growth of top-cell layers for additional devices.

Examples of methods for fabrication of a step-cell tandem device according to some embodiments of the present disclosure involve silicon cell fabrication, III-V cell fabrication, and/or various processes such as epitaxy and wafer bonding.

In FIG. 10, a monocrystalline substrate 1010 is provided whereby the bottom band gap cell 110 is created by junction formation using ion implantation, diffusion, and/or epitaxial growth. Further epitaxial growth can create the (larger) top band gap cell 105 and necessary connection interfaces between bottom 110 and top cells 105 in some embodiments.

Example: Fabrication of Monolithic Dual Junction Step-Cell.

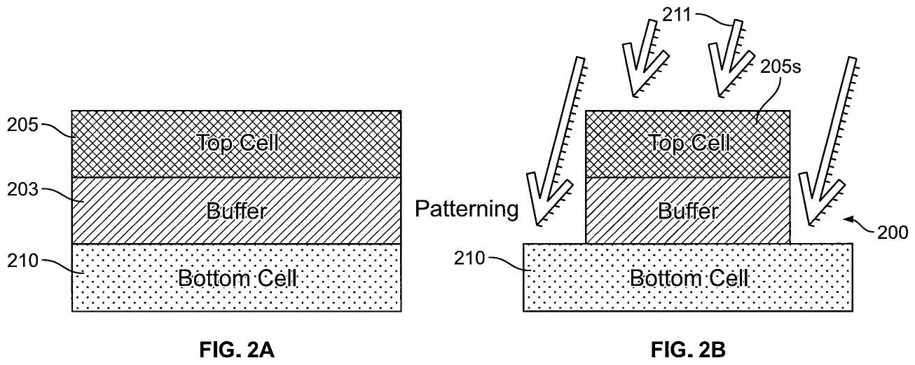

A monolithic two terminal dual junction step-cell 200 connected in series according to some embodiments of the present disclosure is shown in cross-section in FIGS. 2A-2B. The top or upper cell 205, conducting layer (e.g., tunnel diode), and buffer layers 203 that may be required for lattice matching are grown on previously prepared bottom or lower cell 210, as shown in FIG. 2A. An example of materials selection for lattice matching may include silicon germanium (SiGe) for GaAsP growth on Si wafers. The step-cell design 205s was used to boost photogenerated current in the bottom cell 210 in response to incident illumination 211, which may be limited by the absorption in buffer layer 203 as shown in FIG. 2B. That is, the step difference may be defined by removal/patterning or selective deposition/growth of both the top cell 205 and the buffer layers 203, such that the exposed surfaces of the bottom cell 210 are free of both the top cell 205 and the buffer layers 203.

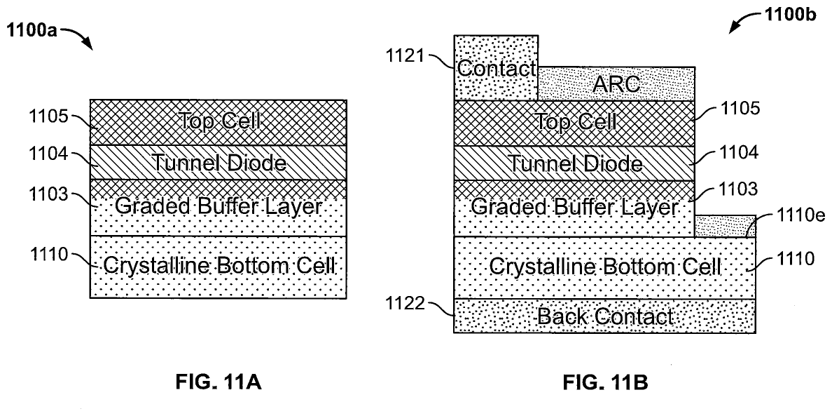

FIG. 11A illustrates an example of a stack 1100a where epitaxial growth of top or upper cell 1105 uses a graded buffer layer 1103, while two subcells are connected via tunnel diode 1104. The top band gap material of the top cell 1105 is etched in some areas down to the bottom band gap cell 1110, exposing a surface of the bottom band gap cell 1110 in those areas in the device 1100b. For a two-terminal device, the top surface of the top band gap cell 1105 provides one contact 1121, and the backside surface of the monocrystalline substrate or the bottom layer of the bottom cell 1110 provides the bottom contact 1122 for the device 1100b, while the stepped surface 1110e of the bottom band gap cell 1110 is free of conductive contacts, as shown in FIG. 11B. In such a two-terminal configuration, the tunnel diode 1104 and low series-resistance interface(s) may be provided between the top 1105 and bottom 1110 cells. Alternatively, contacts can be made to both sides of the cells (top 1105 and bottom 1110), producing a 4-terminal device. In such a 4-terminal device, the materials between the top 1105 and bottom cells 1110 may include an insulator to allow the two-stacked cells 1105, 1110 to operate independently.

In other fabrications, the top/upper and bottom/lower cells are formed on separate monocrystalline substrates. Similar to the monolithic application, a monocrystalline substrate is provided, and implantation or epitaxy is performed to create the bottom cell (FIG. 10). The top cell is created on another separate monocrystalline substrate through methods such as epitaxy. Epitaxy may be a preferred fabrication method in some embodiments since an epitaxial lift-off (ELO) layer can be inserted into the epitaxial structure below the device layers. The top cell is etched (patterned) such that the etched areas are the isolated cell areas, and the etch proceeds to the depth of the ELO layer. Next, the top cell wafer is bonded to the bottom cell wafer such that the top cell is bonded to the bottom cell. By immersion in an etch or exposure to an etch chemistry that attacks the ELO layer, the top cell substrate and any buffer layers below the cell are removed.

Although described an illustrated primarily herein with reference to dual-junction (2J) stacks, it will be understood that multi-junction solar cells in accordance with embodiments of the present disclosure can include stacks of three or more photovoltaic cell layers, for example, by patterning or otherwise removing portions of the topmost layer 105 to expose surfaces of a next layer 115s in the stack, and likewise patterning or otherwise removing portions of the next layer 115s to expose surfaces of a subsequent layer 110 in the stack, and so forth, as shown for example in the device 100e of FIG. 1E. Photovoltaic cell layers described herein may be electrically connected in series or in parallel.

Example: Fabrication of Bonded GaAsP/Si Cell Using SiGe/Si Wafer Carrier.

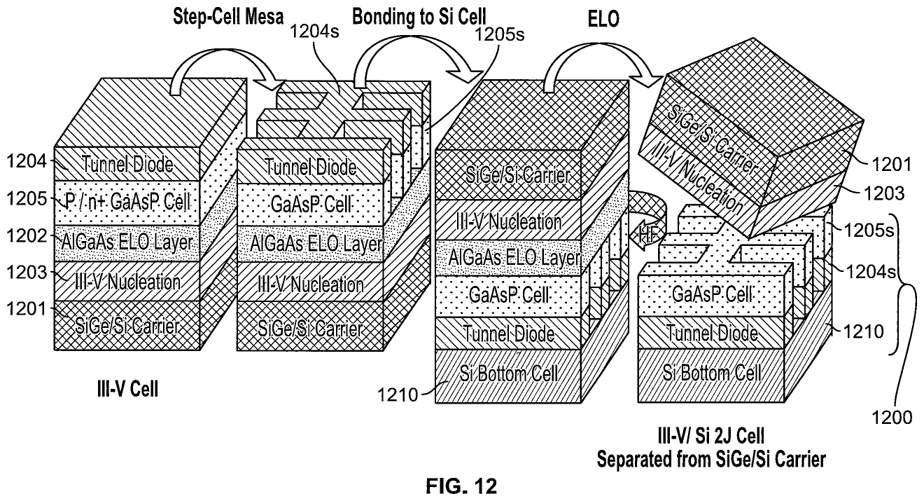

FIG. 12 illustrates one example for the fabrication of a bonded GaAsP/Si cell 1200 according to some embodiments of the present disclosure using SiGe/Si wafer carriers 1201. In this example, aluminum gallium arsenide (AlGaAs) is used as lift-off layer (ELO layer) 1202 and the etch chemistry is hydrofluoric acid (HF). It is understood that process described in FIG. 12 represents one detailed example of generic method described in FIG. 1. The bottom substrate (SiGe/Si stack) 1201 and possible buffer layers (III-V nucleation) 1203 can be re-used for subsequent top cell epitaxy again, which may reduce costs because the substrate 1201 and buffer layers 1203 are re-used. Mesas 1205s of top cells 1205 are left on the bottom cell 1210 with a patterned tunnel diode layer 1204s therebetween after the etch release step. The step cell 1200 is made in such a process because the mesa etching for the top cell 1205, which transfers ‘islands’ 1205s of top cell material (and in some embodiments, islands 1204s of conductive tunnel diode layer 1204), leaves areas that expose the bottom cell 1210 to solar radiation. The area removed in the mesa isolation process of the top cell 1205 is designed for the desired step cell performance in the final structure 1200. Further processing for improved or optimized metal interconnects and ARC depositions is carried out.

Example: Fabrication Methods for Altering Cell Topography and Efficiencies.

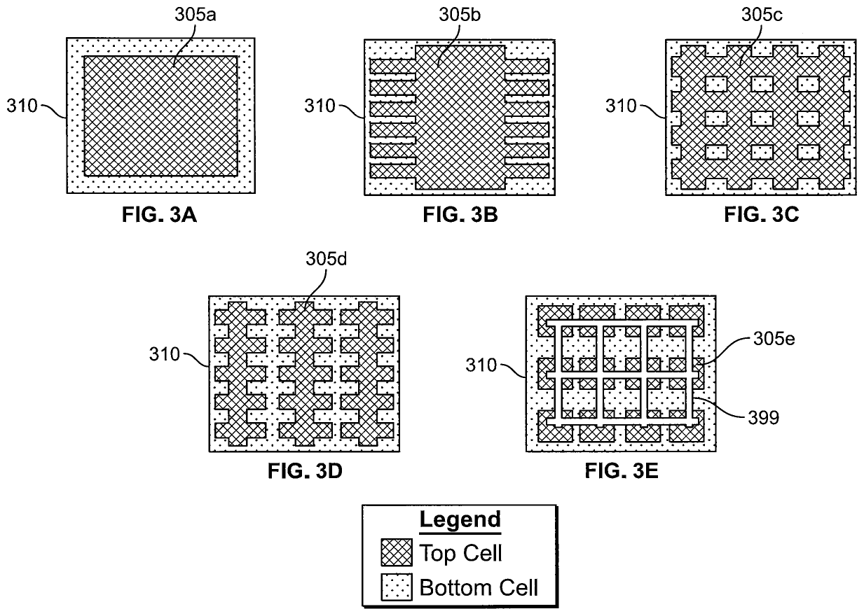

Topography of step cells in accordance with embodiments of the present disclosure can vary using monolithic or bonded step-cell with design and processing optimization as described herein. FIGS. 3A-3E provide examples of various embodiments of the top or upper cell design, where the designs 305a-305b of FIGS. 3A-3B can be used for monolithic cells and the designs 305c-305e of FIGS. 3C-3E can be used for bonded, lift-off step cells on bottom or lower cells 310. In other examples, the bonded, lift-off step cells 305c-305e can be connected into large area solar devices by using metal interconnects; illustrated as lines 399 in FIG. 3E.

Example: Theoretical Analysis of Ideal Step-Cell.

Step-cell designs according to some embodiments of the present disclosure were studied analytically to determine theoretical upper efficiency limit for ideal 2 terminal dual junction step-cell. A schematic representation of a step-cell 400 used for theoretical analysis is shown in FIG. 4A. In FIG. 4A, the top or upper cell 405 bandgap is E_{gT}, while the bottom or lower cell 410 bandgap is E_{gB}. Top cell 405 and bottom cell 410 parts under the top cell have an area Aₜₒₚ, while step part 410e of bottom cell 410 has an area Aₛₜₑₚ. The total device area is represented by Aₜₒₜₐₗ=Aₜₒₚ+Aₛₜₑₚ. The total area of the device (Aₜₒₜₐₗ) is composed of area of the top cell (Aₜₒₚ) and area of the exposed part 410e of the bottom cell (Aₛₜₑₚ, shown as a cross-hatched part of the bottom cell) due to the step difference between the top cell 405 and the bottom cell 410. FIG. 4A illustrates the energy range, E, absorbed in each part of the step-cell.

Top or upper cell photogeneration is due to photons with energy greater than the bandgap of the top or upper cell 405 (E>E_{gT}), while photogeneration of the bottom or lower cell is divided into the step part 410e and the filtered part 410f (having the top or upper cell 405 thereon). Step-part 410e of the bottom cell is exposed to direct sunlight and its photogeneration was due to photons with energy greater than the bandgap of the bottom cell (E>E_{gB}). Filtered part 410f of the bottom cell 410 was placed under top or upper cell 405 and receives the photons that are not absorbed in top or upper cell 405, with energy E_{gT}>E>E_{gB}. In non-ideal situation and for thin top layers, not all of the photons with energy greater than top or upper cell bandgap get absorbed and they also contribute in photogeneration of the bottom cell 410. Optimum efficiency of a step-cell 400 may be limited by an area factor, since increasing the area Aₛₜₑₚ increases total device area but top or upper cell current may remain unchanged. Furthermore, contribution from thermalization losses in the step part 410e of the bottom cell 410 may increase with higher Aₛₜₑₚ area (given that E_{gB}<E_{gT}). There can be an optimum Aₜₒₜₐₗ/Aₜₒₚ ratio, depending on subcells' bandgap and thickness, which provides maximum step-cell efficiency.

FIG. 4B shows calculated short circuit current, I_{SC} (A), in bottom (I_{SCB}, left axis) and top (I_{SCT}, right axis) subcells as a function of top cell bandgap (E_{gT}) in a Si-based 2J step-cell according to some embodiments of the present disclosure for variable Aₜₒₜₐₗ/Aₜₒₚ ratio=1-2 (increasing Aₛₜₑₚ) under AM 1.5G incident spectrum. FIG. 4C shows calculated short open circuit voltage, V_{OC}(V), in bottom (V_{OCB}, left axis) and top (V_{OCT}, right axis) subcells as a function of top cell bandgap (E_{gT}) in a Si-based 2J step-cell according to some embodiments of the present disclosure for variable Aₜₒₜₐₗ/Aₜₒₚratio=1-2 (Aₛₜₑₚ increasing) under AM 1.5G incident spectrum. In FIGS. 4B and 4C, the lowermost solid line (illustrating the case where Aₜₒₜₐₗ=Aₜₒₚ) shows the current in the bottom subcell filtered by the top cell above it.

An upper efficiency limit is shown in FIG. 5, where the effect of Aₜₒₜₐₗ/Aₜₒₚ ratio on a step cell (Aₜₒₜₐₗ/Aₜₒₚ=1-2) for air mass (AM) 1.5G incident spectrum and a temperature T=300 K. Each ratio has a different optimized bandgap combination. A maximum efficiency of 45.78% may be achieved for conventional tandem cell design (Aₜₒₜₐₗ/Aₜₒₚ=1) with 1.64 eV top and 0.96 eV bottom cell bandgaps. However, when top and bottom cell bandgaps vary from the optimized values, the step-cell design according to some embodiments of the present disclosure can provide significant advantages.

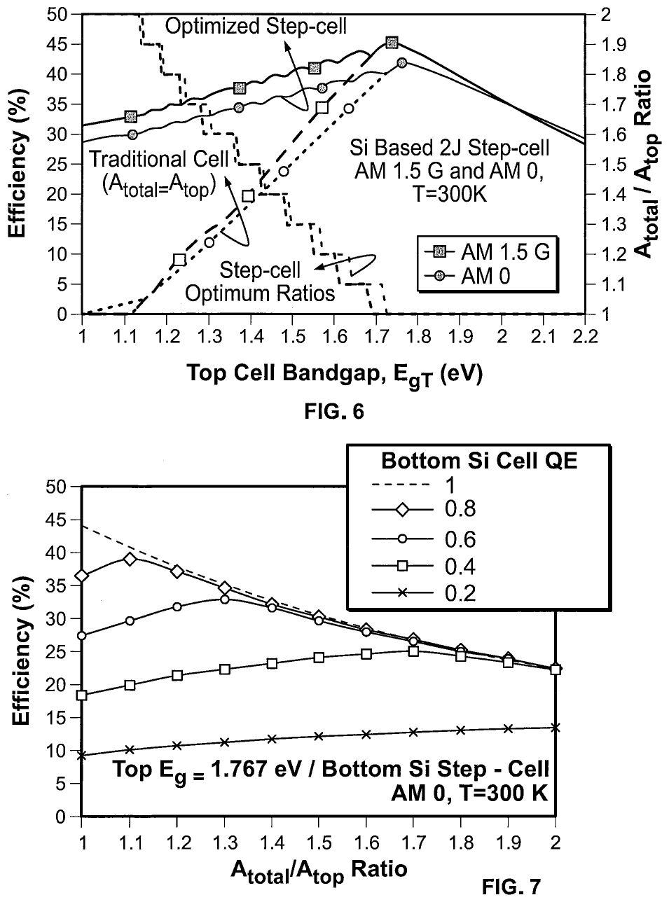

Some benefits of step-cell designs according to some embodiments of the present disclosure for silicon based cells vs. a conventional tandem cell design for cells with non-optimum top or upper cell bandgap can be visualized in FIG. 6. FIG. 6 shows an efficiency limit of a silicon based dual junction (2J) step-cell (full lines) for an optimum Aₜₒₜₐₗ/Aₜₒₚ ratio (dotted lines) as a function of top or upper cell bandgap, under terrestrial and extraterrestrial solar irradiance standards, AM 1.5 G and AM 0 (zero atmosphere) spectra respectively. A conventional tandem 2J cell is also shown for comparison (dashed line).

Once maximum efficiency is achieved (45.1% for top cell E_{gT}=1.73 eV), a conventional tandem cell may be an optimum design. This may be due to the fact that optimum Aₜₒₜₐₗ/Aₜₒₚ ratio may be inversely proportional to the top cell bandgap. When the top cell E_{g} is too high, the top cell may limit current, such that there may be no need for bottom cell enhancement. Step-cell designs according to some embodiments of the present disclosure may provide significant improvement in efficiency limits for cells with non-optimized top-cell bandgap values. In the example of FIG. 6, when the top cell E_{g}=1.41 eV (close to the E_{g} of GaAs), the efficiency upper limit increased from about 21% (in a conventional design where Aₜₒₜₐₗ/Aₜₒₚ=1) to 38.7% (for a step-cell with Aₜₒₜₐₗ/Aₜₒₚ=1.5).

Example: Step-Cell Design for Life-Cycle Degradation

In other applications, a step-cell according to some embodiments of the present disclosure is designed for subcell performance variations during up to the entire life cycle of the tandem solar cell in the field. The degradation of subcells for a given operating environment may be dependent upon their composition, which may include different materials. The fastest-degrading cell will typically dominate, which may direct a design for end-of-life, such that higher efficiency at the beginning of life may not be used in the system and the extra power may be shunted away. The step-cell areas according to some embodiments of the present disclosure are designed to be off the optimum area ratio, creating a constant power output versus time. Potential applications include space applications, where silicon cells degrade from radiation. For example, the area of the silicon lower cell may be larger than the optimal area relative to the upper cell (depending on the material, thickness, and/or surface area thereof), such that the silicon cell delivers slightly more current than that required for current matching. In this setup, area ratio and efficiency of the step-cell may not be initially optimized, but as the silicon cell degrades in the field, the current decreases, moving closer to the current-matched case for the overall tandem cell. That is, the silicon cell may initially generate a current greater than that of the top cell stacked thereon. The efficiency increase from the eventually-resulting optimal area ratio may compensate for the decreased efficiency in the silicon solar cell, resulting over time in an effective ‘radiation-hard’ III-V/Si tandem cell whose performance is relatively stable over its operating lifetime.

In some embodiments, an optimized Si based step-cell for AM 0 spectrum was found to have top bandgap of 1.767 eV. FIG. 7 shows the efficiency limit of a Si based step-cell with 1.767 eV top cell bandgap, as a function of Aₜₒₜₐₗ/Aₜₒₚ Ratio for Si cell quantum efficiency (QE) ranging from 0.2 to 1. As bottom or lower cell performance degrades from space radiation, the overall performance changes to accommodate for the loss of current in the bottom or lower cell. Optimum Aₜₒₜₐₗ/Aₜₒₚ ratio increases with decreasing bottom Si cell QE, while overall maximum efficiency decreases. As an example, for Si QE=1, optimum Aₜₒₜₐₗ/Aₜₒₚ=1 while for Si QE=0.8, optimum ratio is 1.1. These results indicated that step cell designs according to some embodiments of the present disclosure can be optimized to account for cell degradation over time and as such can help maintain more constant power of the cell during its life-cycle.

The optimum area ratios for step-cells may also vary due to finite cell thickness and material quality of both top/upper and bottom/lower cells, as well as material interface.

Example: Simulation of GaAs₁₋ₓPₓ/Si Step-Cells.

GaAs₁₋ₓPₓ/Si step-cells may be desirable since these III-V materials can be fine-tuned to optimum top-cell bandgap. To grow GaAs₁₋ₓPₓ on a Si wafer, lattice graded buffer layers may be required, of which one graded buffer may be SiGe.

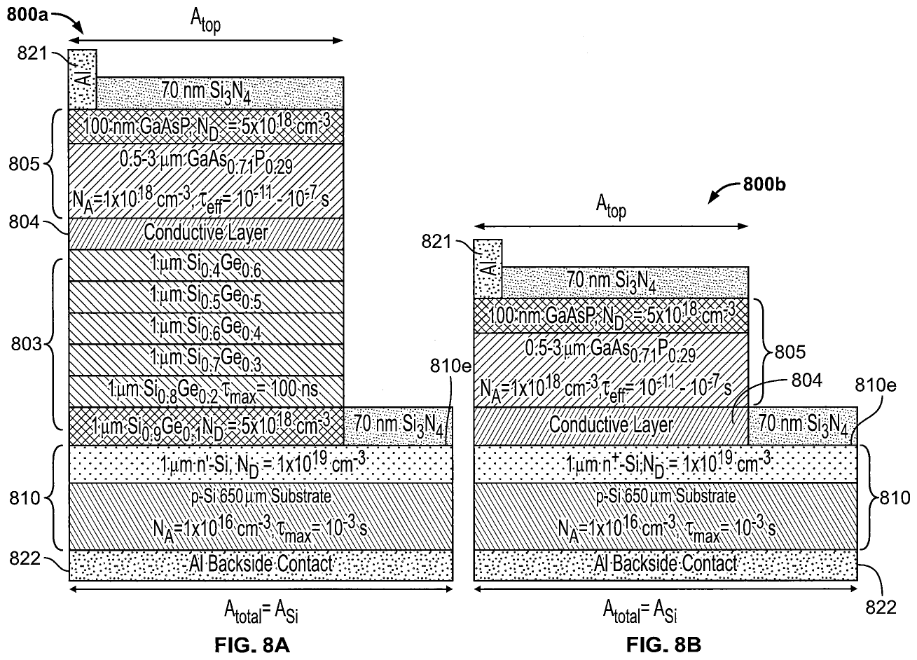

In FIGS. 8A-8B, cross-section and parameters were used to simulate two terminal dual junction GaAs₁₋ₓPₓ/Si step-cells 800a and 800b, with (FIG. 8A) and without (FIG. 8B) graded SiGe buffer layers 803. In the non-buffer layer example 800b, the GaAs₁₋ₓPₓ top cell 805 was bonded onto the silicon cell 810 with a conductive layer (e.g., tunnel diode) 804 therebetween. Conductive contacts (e.g., aluminum contact layers) 821 and 822 are provided on the top surface of the top cell 805 and the backside surface of the bottom cell 1110, respectively, while the stepped surface 810e of the bottom cell 810 is free of conductive contacts 821, 822. The simulation work demonstrated some superiority of bonded GaAs₁₋ₓPₓ/Si step cells 800b compared to monolithic GaAs₁₋ₓPₓ/SiGe/Si step cells 800a.

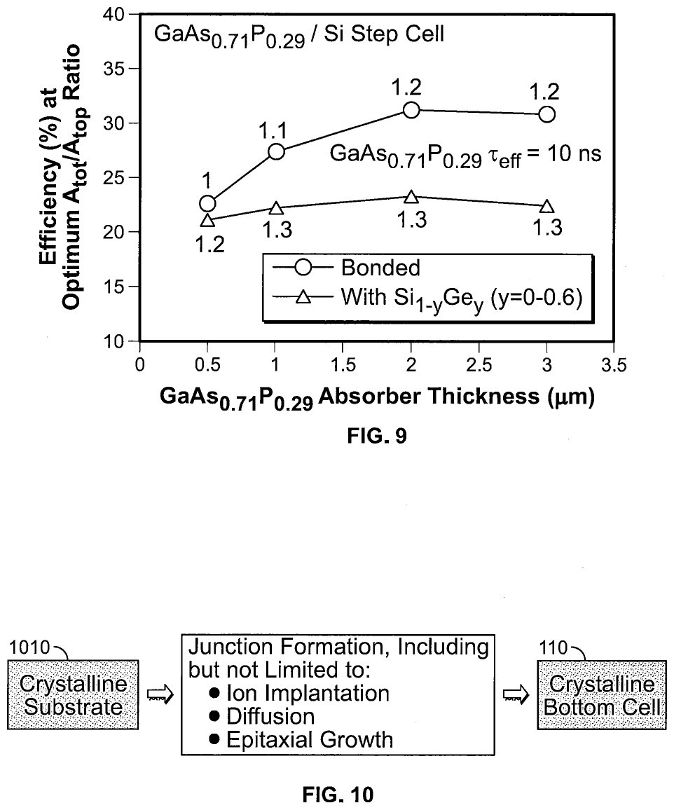

FIG. 9 shows simulated effects of GaAs_{0.71}P_{0.29} absorber layer thickness on the efficiency of the GaAs_{0.71}P_{0.29}/Si tandem step-cell at optimum Aₜₒₜₐₗ/Aₜₒₚ ratio and GaAs_{0.71}P_{0.29} lifetime τ=10 nanoseconds (ns). For sufficiently thin GaAs_{0.71}P_{0.29} layers (below 1 micrometer (μm)), bonded GaAs_{0.71}P_{0.29}/Si tandem cell 800b may be improved or optimized when designed as a conventional tandem cell (Aₜₒₜₐₗ=Aₜₒₚ), since sufficient light reaches bottom Si cell. However, for a SiGe based tandem cell structure with thin GaAs_{0.71}P_{0.29} layers (e.g. 0.5 μm), optimum design may require a step with ratio of about Aₜₒₜₐₗ/Aₜₒₚ=1.2, due to optical losses in SiGe layers. As the top cell absorber thickness increased, more of the bottom Si cell may need to be exposed to incident illumination in order to achieve current matching condition. That is, the surface area of the exposed portions of the bottom Si cell may vary depending on the thickness and material of the top cell. Optimum ratio and top cell absorber thickness may depend both on the bandgap and material quality of the top cell, as well as that of bottom cell.

In other tests, the performance of bonded GaAs₁₋ₓPₓ/Si step cell (x˜0.2) was estimated using measured quantum efficiency of individually fabricated GaAs₁₋ₓPₓ and Si cells and applying a similar approach about optical generation used for theoretical analysis. The analysis showed that for bonded GaAsP/Si with 1-1.5 μm thick GaAsP layers, maximum efficiency may be achieved at optimum area ratio of about Aₜₒₜₐₗ/Aₜₒₚ=1.1. Depending on the subcell thickness and material quality, maximum achievable efficiency may range between about 26% to about 35% (assuming zero reflective and resistive losses).

The present disclosure has been described above with reference to the accompanying drawings, in which embodiments of the invention are shown. However, this disclosure should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. In no event, however, should “on” or “directly on” be construed as requiring a layer to cover an underlying layer.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the invention herein is for the purpose of describing particular embodiments only and is not intended to be limiting of the invention. As used in the description of the invention and the appended claims, the singular forms “a”, “an ” and “the” are intended to include the plural forms as well, unless the context clearly indicates otherwise. It will also be understood that the term “and/or” as used herein refers to and encompasses any and all possible combinations of one or more of the associated listed items, and may be abbreviated as “/”. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, the regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. It will be further understood that terms, such as those defined in commonly used dictionaries, should be interpreted as having a meaning that is consistent with their meaning in the present specification and in the context of the relevant art and will not be interpreted in an idealized or overly formal sense unless expressly so defined herein. All publications, patent applications, patents, and other references mentioned herein are incorporated by reference in their entireties.

Aspects of the present disclosure are described herein with reference to schematic illustrations and/or block diagrams according to embodiments. It is to be understood that the functions/acts may occur out of the order noted in the operational illustrations. For example, two fabrication operations shown in succession may in fact be executed substantially concurrently or the operations may sometimes be executed in the reverse order, depending upon the functionality/acts involved.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments of the present invention described herein, and of the manner and process of making and using them, and shall support claims to any such combination or subcombination.

While some preferred embodiments have been described, other modifications and substitutions may be made thereto without departing from the scope of the current invention. Accordingly, it is to be understood that the current invention has been described by way of illustration and not limitation. That is, although the invention has been described herein with reference to various embodiments, it will be appreciated that further variations and modifications may be made within the scope and spirit of the principles of the invention. Although specific terms are employed, they are used in a generic and descriptive sense only and not for purposes of limitation, the scope of the invention being set forth in the following claims.

1. A multi-junction solar cell, comprising:
a plurality of photovoltaic cell layers electrically connected and stacked to define upper and lower subcells having at least one step difference therebetween that exposes portions of the lower subcell such that, responsive to incident illumination, a current density of the exposed portions of the lower subcell is greater than that of portions thereof having the upper subcell thereon, and respective current densities of the upper and lower subcells are different.

2. The multi-junction solar cell of claim 1, wherein, responsive to the incident illumination, the photovoltaic cell layers are configured to generate respective output currents that are substantially equal.

3. The multi-junction solar cell of claim 2, wherein a surface area of the exposed portions of the lower subcell relative to a surface area of the upper subcell is configured such that the respective output currents thereof are substantially equal responsive to the incident illumination.

4. The multi-junction solar cell of claim 1, wherein the upper subcell comprises a patterned epitaxial photovoltaic cell layer that defines the at least one step difference.

5. The multi-junction solar cell of claim 4, wherein the upper subcell is mechanically bonded to the lower subcell.

6. The multi-junction solar cell of claim 1, wherein the upper subcell comprises pyramid structures, cones, nano-rods, and/or nano-wires that define the at least one step difference.

7. The multi-junction solar cell of claim 4, further comprising:
at least one buffer layer between the upper and lower subcells, wherein the at least one buffer layer comprises a patterned layer that defines a portion of the at least one step difference and exposes the portions of the lower subcell, and
wherein the photovoltaic cell layers define a monolithic structure.

8. The multi-junction solar cell of claim 1, wherein the photovoltaic cell layers comprise features that are configured to facilitate lift-off and separation from a carrier substrate.

9. The multi-junction solar cell of claim 7, wherein the lower subcell comprises a monocrystalline layer.

10. The multi-junction solar cell of claim 1, wherein the lower subcell comprises silicon (Si), wherein the upper subcell comprises gallium arsenide phosphide (GaAsP), and wherein the at least one buffer layer comprises graded silicon germanium (SiGe) or graded GaAsP graded for lattice matching.

11. The multi-junction solar cell of claim 1, wherein the upper subcell and the lower subcell comprise respective materials that are configured to generate different output currents responsive to the incident illumination at a beginning-of-life based on degradation of the respective materials, and to subsequently generate substantially equal output currents responsive to the incident illumination.

12. The multi-junction solar cell of claim 1, wherein responsive to the incident illumination, the exposed portions of the lower subcell are configured to generate a greater portion of an output current thereof than portions thereof having the upper subcell thereon.

13. The multi-junction solar cell of claim 1, wherein the exposed portions of the lower subcell are free of conductive contact layers.

14. A multi-junction solar cell, comprising:
a plurality of photovoltaic cell layers electrically connected and stacked to define at least one upper subcell and a lower subcell having at least one step difference therebetween that exposes portions of the lower subcell such that, responsive to incident illumination, a current density of the exposed portions of the lower subcell is greater than that of portions of the lower subcell having the upper subcell thereon,
wherein the lower subcell comprises silicon (Si), wherein the at least one upper subcell comprises a group III-V material.

15. The multi-junction solar cell of claim 14, wherein the at least one upper subcell comprises gallium arsenide phosphide (GaAsP).

16. The multi-junction solar cell of claim 14, wherein the at least one upper subcell is mechanically bonded to the lower subcell.

17. The multi-junction solar cell of claim 16, wherein the at least one upper subcell comprises features that are configured to facilitate lift-off and separation from a carrier substrate.

18. The multi-junction solar cell of claim 14, wherein the lower subcell comprises monocrystalline Si, and wherein at least one upper subcell comprises at least one patterned epitaxial photovoltaic cell layer that defines the at least one step difference.

19. The multi-junction solar cell of claim 18, further comprising at least one buffer layer comprising graded silicon germanium (SiGe) or graded gallium arsenide phosphide (GaAsP) between the lower subcell and the at least one upper subcell.
